(19) United States
(12) Patent Application Publication
(10) Pub. No.: US 2009/0152743 A1
(43) Pub. Date: Jun. 18, 2009

(54) ROUTING LAYER FOR A MICROELECTRONIC DEVICE, MICROELECTRONIC PACKAGE CONTAINING SAME, AND METHOD OF FORMING A MULTI-THICKNESS CONDUCTOR IN SAME FOR A MICROELECTRONIC DEVICE

(76) Inventors: Houssam JOMAA, Phoenix, AZ (US); Islam A. SALAMA, Chandler, AZ (US); Yonggang LI, Chandler, AZ (US)

Correspondence Address: Kenneth Nelson;Intel Corporation, c/o Intellevate, LLC, P.O. Box 52050, Minneapolis, MN, 55402, US

(21) Appl. No.: 11/957,454

(22) Filed: Dec. 15, 2007

(51) Int. Cl. H01L 23/52; H01L 21/768

(52) U.S. Cl. 257/782; 438/673; 257/E23.141; 257/E21.575

(57) ABSTRACT

A routing layer for a microelectronic device includes a first region (110, 510) containing a first trench (111, 511), a second region (120, 520) containing a second trench (121, 521), and an electrically conductive material (230, 530) in the first trench and in the second trench. The first trench has a first depth (115) and the second trench has a second depth (125) that is different from the first depth.

### FIELD OF THE INVENTION

The disclosed embodiments of the invention relate generally to circuit patterns in microelectronic devices, and relate more particularly to circuit patterns having different thicknesses in different regions of a routing layer.

### BACKGROUND OF THE INVENTION

Circuits on routing layers are typically made using a technique known as the semi-additive process (SAP), which forms electrically conductive features above the surface of a dielectric material. A feature of the semi-additive process is that it permits only a single pattern thickness everywhere on a particular routing layer. Accordingly, if pattern thickness must be kept to a certain minimum in one region of a routing layer (e.g., in a necking region where many fine signal traces crowd together to escape from underneath the die area) that same minimum thickness must be used everywhere else on the routing layer, including in the main routing region of a layer where the additional available space would permit thicker traces, and hence more margin for impedance control for electronic circuits, if not for the thickness restrictions imposed by the fine trace and spacing.

### BRIEF DESCRIPTION OF THE DRAWINGS

The disclosed embodiments will be better understood from a reading of the following detailed description, taken in conjunction with the accompanying figures in the drawings in which:

FIGS. 1 and 2 are perspective views of a portion of a routing layer for a microelectronic device according to an embodiment of the invention;

FIG. 3 is a plan view of a portion of a microelectronic package according to an embodiment of the invention;

FIG. 4 is a front elevational view of a portion of a routing layer according to an embodiment of the invention;

FIG. 5 is a perspective view of a portion of another microelectronic package according to an embodiment of the invention;

FIG. 6 is a flowchart illustrating a method of forming a multi-thickness conductor for a microelectronic device according to an embodiment of the invention; and

FIG. 7 is a plan view of a mask that may be used to dynamically shape a laser beam according to an embodiment of the invention.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,”, “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “in one embodiment” herein do not necessarily all refer to the same embodiment.

### DETAILED DESCRIPTION OF THE DRAWINGS

In one embodiment of the invention, a routing layer for a microelectronic device comprises a first region containing a first trench, a second region containing a second trench, and an electrically conductive material in the first trench and in the second trench. The first trench has a first depth, the second trench has a second depth, and the first depth is different from the second depth. The electrically conductive material in the first and second trenches is a signal trace that at least partially extends below the surface of the routing layer.

As mentioned above, if the semi-additive process were used to form a particular signal trace then the same thickness would have to be used for every other signal trace on the same routing layer. Under that scenario, if certain considerations (e.g., a lack of space in a necking region) dictate a particular thickness, that same thickness must be used everywhere else on the routing layer, even in regions where the considerations do not apply. As advances in semiconductor technology enable smaller and smaller devices packed more and more densely, corresponding decreases in minimum signal trace thicknesses (which decreases are necessary in order to maintain the aspect ratio for the dry film resist in the formation of such traces) lead to compromises in impedance, impedance variation, insertion loss, and the like. Embodiments of the invention remove the single-thickness restriction in the main routing area (which dictates circuit performance), thus providing the ability to create conductor lines that are thicker in the main routing region (or elsewhere) than in the necking region and therefore improving electrical performance.

In general, thicker traces provide better margin for impedance, impedance variation, and insertion loss. In at least some embodiments, trace thickness is more important in the main routing area of a routing layer, and embodiments of the invention allow dual-depth (or other multi-depth) laser-formed trenches (using, for example, laser projection patterning (LPP)) to ensure proper electrical performance. As the previous sentence suggests, the invention is not limited to trenches of just two different depths; trenches having any number of different depths may be formed using embodiments of the invention.

As a particular example, the thickness target for a conductor (usually copper) trace on the routing layer in one technology generation may be 15 micrometers, while in a later technology generation, yield and substrate manufacturing (and/or other) issues may force the copper thickness target down to 10 micrometers with spaces between copper traces also of 10 micrometers. (This particular arrangement of fine lines and spaces is sometimes abbreviated as “10/10 L/S.”) With the semi-additive process, the reduced copper thickness would impact the entire routing layer, including the main routing region, to the detriment of electrical performance. In contrast, embodiments of the invention use the LPP process to form conductor lines by embedding them in the dielectric material. This fundamental difference allows the variation of trench depth in different areas of the routing layer, thereby decoupling trace thickness in the main routing and necking regions and providing better electrical margin for substrates prepared using techniques according to embodiments of the invention. No longer need trace thickness in the main routing region be sacrificed for the trace thickness requirements in the necking region. (Of course, manufacturing process limitations and electrical performance may not necessarily be limited to 10 micrometer thickness and/or to 10/10 L/S with the semi-additive process.)

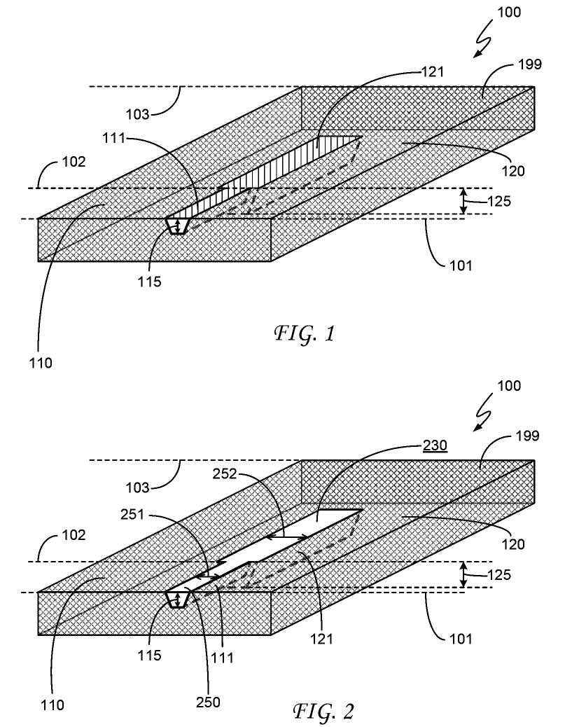

Referring now to the drawings, FIGS. 1 and 2 are perspective views of a portion of a routing layer 100 for a high density interconnect (HDI) substrate or board (or other microelectronic device) according to an embodiment of the invention. (The portion of the routing layer will hereinafter be referred to simply as “routing layer 100.”) Portions of routing layer 100 are drawn so as to appear partially transparent so that underlying features of routing layer 100 may be seen.

As illustrated in FIG. 1, routing layer 100 comprises a dielectric material 199 having a region 110 (between dotted lines 101 and 102) containing a trench 111 and a region 120 (between dotted lines 102 and 103) containing a trench 121. As an example, region 110 can be a necking region of routing layer 100—i.e., a region within the footprint of a die (not shown) that is subsequently added above routing layer 100—and region 120 can be a routing region of routing layer 100—i.e., a region that lies outside of the die footprint. It will be understood that the necking region contains less area for the routing of traces than does the routing region and that the traces must accordingly be made smaller and packed more closely together in the necking region than in the routing region usually in order to route input/output (I/O) traces between die bumps. Regions 110 and 120 are also shown in FIG. 3, described below.

FIG. 1 depicts trenches 111 and 121 before they are filled with electrically conductive material so that the dimensions of the trenches may more clearly be seen. Trench 111 has a depth 115 and trench 121 has a depth 125. Depths 115 and 125 are different from each other. In the illustrated embodiment, depth 125 is greater than depth 115.

As depicted in FIG. 1, trench 111 and trench 121 have adjacent ends that are open to each other such that the trenches flow into each other. (The trenches may alternatively be described as two portions of a single trench, and that description will at times be used below.) The placement of an electrically conductive material in trenches 111 and 121 electrically couples the two trenches to each other and creates a signal trace capable of carrying electrical current.

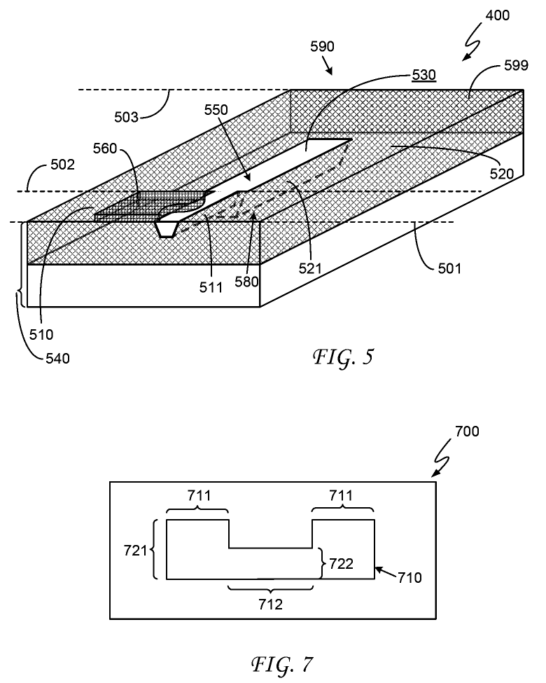

Referring now to FIG. 2, routing layer 100 further comprises an electrically conductive material 230 (e.g., copper or the like) in trenches 111 and 121. Electrically conductive material 230 in trenches 111 and 121 forms a trace 250 (e.g., a fine line trace) in routing layer 100. Trace 250 has a width 251 in region 110 and a width 252 in region 120. In the embodiment illustrated in FIG. 2, width 252 is greater than width 251. It should be noted that normally a trace bends as it fans out, and the trace may change width across the bends. The abrupt, straight-line width changes shown in FIGS. 1 and 2 (and in FIG. 5, discussed below) are used in the figures in order to more clearly show the changes in width.

In various embodiments, one or both of trenches 111 and 121 have an aspect ratio of 1:1 (or approximately 1:1). In other words, in those embodiments, depth 115 and width 251 and/or depth 125 and width 252 are equal or approximately equal to each other. In different embodiments, one or both of trenches 111 and 121 have other aspect ratios. In general, and for manufacturing purposes, the trench width and depth are usually related by an aspect ratio of between 1 and 1.5 to 1. In that sense, a depth of 10-15 microns is used for a trench width of 10 microns. Of course, the closer the aspect ratio value is to unity the better the yield and throughput time of the manufacturing process usually is, but this does not mean that the laser patterning process is limited to this aspect ratio range, since aspect ratios of greater than 1.5:1 may in some cases be used, but in general those larger aspect ratios will impact process yield.

FIG. 3 is a plan view of a portion of a microelectronic package 300 according to an embodiment of the invention. As illustrated in FIG. 3, microelectronic package 300 comprises routing layer 100 and a die 360 over routing layer 100. Die 360 is shown in dotted lines to indicate that it is depicted as being transparent so that underlying interconnect structures 345 may be seen. (Although interconnect structures 345 are shown as being located only along or under one edge of die 360 they may, in other embodiments, occupy other locations instead of or in addition to those shown. Furthermore, although die 360 is shown as being square, it may in other embodiments have some other shape, and may be larger or smaller than depicted in relationship to routing layer 100.)

As shown, region 110 includes the area where traces 250 must pass between interconnect structures 345 (which are usually die bumps or pads). Because space is much more limited in this area than it is elsewhere, region 110, as mentioned above, is often referred to as a necking region by analogy to the neck of a bottle, which is narrow in comparison to the bottle's other parts. Region 120, as also mentioned above, is often referred to as the main routing region, or simply the routing region, because of the abundance of space available to route traces. Although region 120 is only labeled as being the region to the left of the die footprint in FIG. 3, it should be understood that all parts of routing layer 100 that lie outside of the die footprint form a part of region 120, i.e., the routing region, whether or not a trace actually occupies any particular portion of that space.

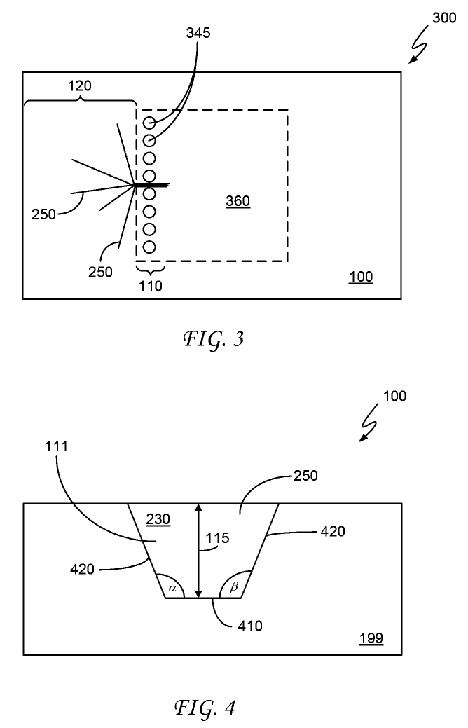

FIG. 4 is a front elevational view of routing layer 100 according to an embodiment of the invention. As illustrated in FIG. 4, trench 111 comprises a floor 410 and sidewalls 420 extending away from floor 410. Trench 111 further comprises an internal angle α between floor 410 and one of sidewalls 420 and an internal angle β between floor 410 and another one of sidewalls 420. (Although not depicted in FIG. 4, trench 121 may also have a floor and sidewalls, and these may have the same geometrical relationship to one another as do floor 410 and sidewalls 420 in trench 111.) In one embodiment, angle α is no greater than approximately 120 degrees. In the same or another embodiment, angle β is no greater than approximately 120 degrees. In at least one embodiment, angle α and angle β are equal to each other and neither are greater than approximately 120 degrees. In a particular embodiment, angle α is no greater than approximately 100 degrees and no less than approximately 90 degrees. In various embodiments trench 121 may have the same or similar parameters or geometrical relationships as have just been described for trench 111.

FIG. 5 is a perspective view of a portion of a microelectronic package 500 according to an embodiment of the invention. As illustrated in FIG. 5, microelectronic package 500 comprises a substrate 540 and a die 560 over substrate 540. Only a portion of die 560 is shown in the figure, and that portion is partially transparent so that underlying features of microelectronic package 500 may be seen. Substrate 540 includes a routing layer 590 that comprises a dielectric material 599 having a region 510 (between dotted lines 501 and 502) and a region 520 (between dotted lines 502 and 503). Region 510 contains a portion 511 of a trench 580. Region 520 contains a portion 521 of trench 580. An electrically conductive material 530 is in trench 580. Electrically conductive material 530 and portions 511 and 521 of trench 580 form a trace 550 (e.g., a fine line trace) of microelectronic package 500.

As an example, routing layer 590 can be similar to routing layer 100 that is first shown in FIG. 1. Accordingly, region 510, region 520, electrically conductive material 530, and trace 550 can be similar to, respectively, region 110, region 120, electrically conductive material 130, and trace 150, all of which are first shown in FIG. 1. Similarly, portion 511 and portion 521 of trench 580, including their aspect ratios, internal angles, and other dimensions, can be similar to, respectively, trench 111 and trench 121 that are also first shown in FIG. 1. Consistent with that similarity, portion 511 of trench 580 has a first depth, portion 521 of trench 580 has a second depth, and the first depth is different from the second depth. In the illustrated embodiment, the first depth is less than the second depth.

A generalized process flow for the formation of a routing layer with traces will now be presented. First, buildup material lamination may be performed according to techniques known in the art. In one embodiment the lamination may be done with half curing for dimensional stability. Second, laser vias may be drilled with a CO₂ laser or another type of laser in order to form the interconnects between two adjacent layers. In one embodiment, the vias may be drilled (or otherwise formed) at the same time that the trenches are formed.

Following the via formation, an LPP process may be used to form the trenches on the surface of the substrate. Dual-depth (or other multi-depth) trenches can then be achieved using techniques according to embodiments of the invention, as discussed in more detail elsewhere herein. Traces formed with LPP normally assume an aspect ratio of between about 4:1 to 5:1 (depth to width) due to trench wall tapering from the laser ablation process of LPP. Hence, reduction in trace depth allows the definition of finer traces, a feature that is especially important in the necking area. Trench depth can be easily tailored to meet specific electrical and high speed I/O requirements.

After the formation of dual-depth (or other multi-depth) trenches, electroless copper may be deposited onto the trenches and vias on the substrate. This may be followed by an electrolytic copper (or other electrically conductive material) plating process. Finally, a CMP process may be performed in order to remove the over plated copper (or other material) and in order to allow conductor line isolation. It should be noted here that embodiments of the invention are not constrained by metallization solution, meaning that any combination of metallization solutions may be used in connection with embodiments of the invention.

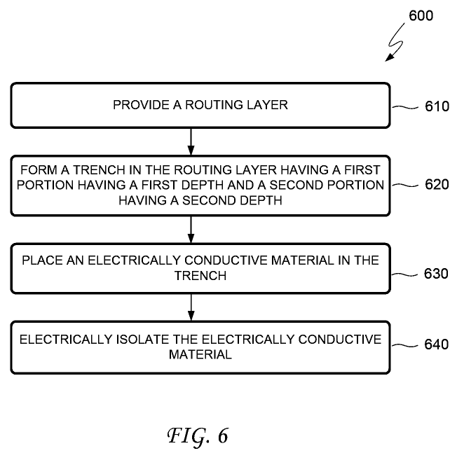

FIG. 6 is a flowchart illustrating a method 600 of forming a multi-thickness conductor for a microelectronic device according to an embodiment of the invention. A step 610 of method 600 is to provide a routing layer. As an example, the routing layer can be similar to routing layer 100 that is first shown in FIG. 1.

A step 620 of method 600 is to form a trench in the routing layer having a first portion having a first depth and a second portion having a second depth. As an example, the trench can be similar to trench 580 that is first shown in FIG. 5. The first and second portions of the trench can be similar to, respectively, portion 511 and portion 521 of trench 580 that are first shown in FIG. 5. Alternatively, the first and second portions of the trench can be similar to, respectively, trench 111 and trench 121, both of which are first shown in FIG. 1, and the trench itself can be similar to the combination of trenches 111 and 121.

In one embodiment, step 620 comprises ablating a portion of the routing layer using a laser. In one manifestation of that embodiment, step 620 further comprises tuning an energy density of the laser using a gray-scale mask. A gray-scale mask has different regions having differing transmissivities. Accordingly, a gray-scale mask may be prepared so as to have a number of regions that are opaque to the laser energy and a number of other regions that are transmissive to the laser energy in varying degrees. The transmissive regions may correspond to, and line up with, the first and second portions of the trench, with the transmissive region corresponding to the deeper portion of the trench being more transmissive to the laser energy than the transmissive region corresponding to the more shallow portion of the trench. The opaque regions may correspond to, and line up with, regions of the routing layer where no trench is to be formed. As an example, the gray-scale mask may be constructed of glass or doped glass, copper, chromium, aluminum, or another ultra-thin metal (less than approximately 100 nanometers), a dielectric material, or the like. Dielectric materials may be advantageous in some embodiments because they are not limited by thickness and because they tend to be tougher than metal at the metal thicknesses used.

In another manifestation of the laser ablation embodiment, step 620 further comprises forming the first portion of the trench using a first laser ablation condition and forming the second portion of the trench using a second laser ablation condition. As an example, the first laser ablation condition could be a particular laser energy value and the second laser ablation condition could be a different laser energy value. As another example, the first laser ablation condition could be a particular speed at which a table carrying the routing layer moves under the laser (or at which the laser moves over the routing layer) and the second laser ablation condition could be a different speed at which the table carries the routing layer (or at which the laser moves over the routing layer).

As an example, the first portion of the trench may be exposed to the laser and the second portion of the trench may be shielded from the laser (or vice versa, as the case may be) using a binary mask. A binary mask contains portions that are fully transmissive to the laser energy and portions that are completely opaque to it. A properly-constructed binary mask may thus allow the exposure of a particular region of the routing layer while preventing such exposure to a different region. When the particular region has been exposed to the laser as desired, a different binary mask may be used to allow exposure of the different region while shielding the particular region. As an example, a first binary mask may prevent laser energy from reaching the necking area while permitting laser energy to reach the main routing region and a second binary mask may do the opposite, i.e., prevent laser energy from reaching the main routing region while permitting it to reach the necking region. In this way the first and second portions of the trench may be formed under different exposure conditions.

Because the first and second portions of the trench are formed at different times, this manifestation of the laser ablation embodiment may require the further step of stitching together the first portion and the second portion of the trench using a high precision positioning system. Because this stitching requires a high degree of accuracy, it may in one embodiment be accomplished using a positioning system that includes high accuracy motion apparatus and control mechanisms or the like.

In another manifestation of the laser ablation embodiment, step 620 further comprises dynamically shaping a beam of the laser such that the beam has a first shape while it forms the first portion of the trench and a second shape while it forms the second portion of the trench. As an example, dynamically shaping the laser beam comprises controlling a width of the laser beam using an aperture. A mask with such an aperture is depicted in FIG. 7, discussed below.

A step 630 of method 600 is to place an electrically conductive material in the trench. As an example, the electrically conductive material can be similar to electrically conductive material 230 that is first shown in FIG. 2. In one embodiment, step 630 comprises electrolessly plating a first metal layer in the trench and then electrolytically plating a second metal layer in the trench over the first metal layer. It will be understood that this or other embodiments may result in some degree of overplating that must be addressed in order for the multi-thickness conductor to function properly, as further explained in the following step.

A step 640 of method 600 is to electrically isolate the electrically conductive material. As an example, the overplated copper or other metal that was mentioned above in connection with step 630 must be removed in order to electrically isolate the electrically conductive material in the trench from electrically conductive material located in other trenches and elsewhere on the routing layer or other locations in the microelectronic device. In one embodiment, step 630 comprises performing a chemical mechanical polishing (CMP) operation.

FIG. 7 is a plan view of a mask 700 that may be used to dynamically shape a laser beam according to an embodiment of the invention. As illustrated in FIG. 7, mask 700 comprises an aperture 710 having a region 711 with a width 721 and a region 712 with a width 722. In the illustrated embodiment, width 721 is twice the size of width 722. As a routing layer moves at a constant speed underneath a laser, a laser beam projected onto a routing layer through mask 700 spends twice as much time shining on portions of the routing layer that lie within the borders of region 711 than on portions that lie within the borders of region 712. Accordingly, the region 711 portions are exposed to twice as much laser energy as the region 712 portions. It will be understood that different exposure gradients may be achieved by making appropriate changes to the size and shape of aperture 710 and/or to the speed at which the routing layer is moved with respect to the laser.

Although the invention has been described with reference to specific embodiments, it will be understood by those skilled in the art that various changes may be made without departing from the spirit or scope of the invention. Accordingly, the disclosure of embodiments of the invention is intended to be illustrative of the scope of the invention and is not intended to be limiting. It is intended that the scope of the invention shall be limited only to the extent required by the appended claims. For example, to one of ordinary skill in the art, it will be readily apparent that the microelectronic package and related routing layers and methods discussed herein may be implemented in a variety of embodiments, and that the foregoing discussion of certain of these embodiments does not necessarily represent a complete description of all possible embodiments.

Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

What is claimed is:

1. A routing layer for a microelectronic device, the routing layer comprising:
a first region containing a first trench and a second region containing a second trench; and
an electrically conductive material in the first trench and in the second trench,
wherein:
the first trench has a first depth;
the second trench has a second depth; and
the first depth is different from the second depth.

2. The routing layer of claim 1 wherein:
the first region is a necking region of the routing layer.

3. The routing layer of claim 2 wherein:
the first depth is less than the second depth.

4. The routing layer of claim 1 wherein:
the second region is a routing region of the routing layer.

5. The routing layer of claim 4 wherein:
the second depth is greater than the first depth.

6. The routing layer of claim 1 wherein:
the first trench and the second trench each have a floor and a sidewall extending away from the floor; and
at least one of the first trench and the second trench have an internal angle between the floor and the sidewall of no greater than approximately 120 degrees.

7. The routing layer of claim 1 wherein:
the electrically conductive material comprises copper.

8. The routing layer of claim 7 wherein:
the first trench, the second trench, and the electrically conductive material form a fine-line trace of the routing layer.

9. A microelectronic package comprising:
a substrate; and
a die over the substrate,
wherein:
the substrate comprises a routing layer;
the routing layer comprises:
a first region containing a first portion of a trench;
a second region containing a second portion of the trench; and
an electrically conductive material in the trench;
the first portion of the trench has a first depth;
the second portion of the trench has a second depth; and
the first depth is different from the second depth.

10. The microelectronic package of claim 9 wherein:
the first region is a necking region of the routing layer;
the second region is a routing region of the routing layer; and
the first depth is less than the second depth.

11. The microelectronic package of claim 9 wherein:
the electrically conductive material comprises copper; and
the first portion of the trench, the second portion of the trench, and the electrically conductive material form a fine-line trace of the routing layer.

12. The microelectronic package of claim 9 wherein:
the first portion of the trench and the second portion of the trench each have a floor and a sidewall extending away from the floor; and
at least one of the first portion of the trench and the second portion of the trench have an internal angle between the floor and the sidewall of no greater than approximately 120 degrees.

13. A method of forming a multi-thickness conductor for a microelectronic device, the method comprising:
providing a routing layer;
forming a trench in the routing layer, the trench having a first portion having a first depth and a second portion having a second depth; and
placing an electrically conductive material in the trench.

14. The method of claim 13 wherein:
forming the trench comprises ablating a portion of the routing layer using a laser.

15. The method of claim 14 wherein:
forming the trench further comprises tuning an energy density of the laser using a gray-scale mask.

16. The method of claim 14 wherein:
forming the trench further comprises:
forming the first portion of the trench using a first laser ablation condition; and
forming the second portion of the trench using a second laser ablation condition.

17. The method of claim 14 wherein:
forming the trench further comprises using a binary mask to expose only one of the first portion and the second portion during a particular exposure of the trench to the laser.

18. The method of claim 17 further comprising:
stitching together the first portion and the second portion using a positioning system.

19. The method of claim 14 wherein:
the laser has a laser beam; and
forming the trench comprises dynamically shaping the laser beam such that the laser beam has a first shape while it forms the first portion of the trench and a second shape while it forms the second portion of the trench.

20. The method of claim 19 wherein:
dynamically shaping the laser beam comprises controlling a width of the laser beam using an aperture.

21. The method of claim 14 wherein:
placing the electrically conductive material in the trench comprises:
electrolessly plating a first metal layer in the trench; and
electrolytically plating a second metal layer in the trench over the first metal layer.

22. The method of claim 14 further comprising:
electrically isolating the electrically conductive material.
